(19) United States
(12) Patent Application Publication
(10) Pub. No.: US 2021/0159068 A1
(43) Pub. Date: May 27, 2021

(54) LOW VOLATILITY MATERIAL REMOVAL FROM A SEMICONDUCTOR DEVICE

(71) Applicant: APPLIED MATERIALS, INC., Santa Clara, CA (US)

(72) Inventors: Glen F. R. Gilchrist, Danvers, MA (US); Shurong Liang, Lynnfield, MA (US); Il-Woong Koo, Gloucester, MA (US)

(73) Assignee: APPLIED MATERIALS, INC., Santa Clara, CA (US)

(21) Appl. No.: 16/789,880

(22) Filed: Feb. 13, 2020

Related U.S. Application Data
(60) Provisional application No. 62/938,453, filed on Nov. 21, 2019.

(51) Int. Cl. H01L 21/02; H01L 21/67; H01L 21/68; B08B 5/00; B08B 7/00

(52) U.S. Cl. CPC H01L 21/02057; H01L 21/67115; B08B 7/0071; H01L 21/68; B08B 5/00; H01L 21/67028

(57) ABSTRACT

Disclosed herein are methods of removing material, such as processing byproducts from a semiconductor device. In one approach, the method includes providing a wafer adjacent a halo, wherein the wafer and the halo are disposed within a chamber, and wherein the wafer includes a first wafer edge and a second wafer edge, moving the wafer and the ion source relative to one another, and varying at least one of the following processing parameters as the ion source passes the first wafer edge or the second wafer edge: a scan speed, a temperature at the halo and the wafer, a gas flow rate of the ion source, and a power of the ion source.

### RELATED APPLICATION

This application claims priority to U.S. provisional patent application 62/938,453, filed Nov. 21, 2019, entitled “Low Volatility Material Removal from a Semiconductor Device,” and incorporated by reference herein in its entirety.

### FIELD OF THE DISCLOSURE

The present disclosure relates to semiconductor devices, and more particularly, to approaches for removing low-volatility material from 3-dimensional semiconductor device structures.

### BACKGROUND OF THE DISCLOSURE

Fabrication of advanced 3D semiconductor device structures requires removal of a variety of different materials having different chemical reactivity and volatility for the original material and the reaction byproducts. Some materials and byproducts have low volatility and remain on the device structure as residue resulting in device failure or poor device performance. Thus, there is a need for techniques to remove low volatility material from 3D semiconductor device structures.

### SUMMARY OF THE DISCLOSURE

In one approach, a method may include providing a wafer adjacent a halo, wherein the wafer and the halo are disposed within a chamber, and wherein the wafer includes a first wafer edge and a second wafer edge. The method may further include moving the wafer and the ion source relative to one another, and varying at least one of the following processing parameters as the ion source passes the first wafer edge or the second wafer edge: a scan speed, a temperature at the halo and the wafer, a gas flow rate of the ion source, and a power of the ion source.

In another approach, a method of removing material and byproducts from a semiconductor device may include providing a wafer connected to a halo, wherein the wafer and the halo are disposed within a chamber, and wherein the wafer includes a first wafer edge and a second wafer edge. The method may further include scanning the wafer with the ion source, and varying at least one of the following processing parameters as the ion source scans over the first wafer edge or the second wafer edge: a scan speed, a temperature at the halo and the wafer, a gas flow rate of the ion source, and a power of the ion source.

In yet another approach, a method of removing material and byproducts from a semiconductor device may include providing a wafer assembly within a chamber, wherein the wafer assembly includes a wafer coupled to a halo, and wherein the wafer is defined by a wafer perimeter. The method may further include scanning the wafer and the halo with an ion source, and processing the wafer according to a first set of processing parameters when the ion source is aligned with a first area of the halo located outside the wafer perimeter. The method may further include processing the wafer according to a second set of processing parameters when the ion source is aligned with the wafer, wherein the first and second sets of processing parameters include: a scan speed, a temperature at the halo and the wafer, a gas flow rate of the ion source, or a power of the ion source.

### BRIEF DESCRIPTION OF THE DRAWINGS

FIGS. 1A-1C are block diagrams depicting scan movement in accordance with embodiments of the present disclosure.

FIGS. 2A-2C are block diagrams depicting scan movement in accordance with embodiments of the present disclosure.

FIGS. 3A-3C are block diagrams depicting scan movement in accordance with embodiments of the present disclosure.

FIGS. 4A-4C are block diagrams depicting scan movement in accordance with embodiments of the present disclosure.

FIG. 5 is a flowchart depicting a method in accordance with embodiments of the present disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where embodiments are shown. The methods, systems, and devices may be embodied in many different forms and are not to be construed as being limited to the embodiments set forth herein. Instead, these embodiments are provided so the disclosure will be thorough and complete, and will fully convey the scope of methods, systems, and devices to those skilled in the art.

This disclosure combines multiple variables, in an advantageous and novel way, to provide an apparatus and a method to remove low volatility material, including etch reaction byproducts, created during formation of 3-D semiconductor devices. Low volatility material may be present on a wafer as a condensed solid, which slowly loses molecules to the gas phase through sublimation. In a closed system, the relation between the solid phase and gas phase (or between a liquid phase and the gas phase) may be described by the vapor pressure, Pv [1]:

ln(Pᵥ)=C−ΔH_{vap,m}/RT

In this equation, C is a constant, ΔH_{vap,m} is the molar enthalpy of vaporization, R is the gas constant, and T is the absolute temperature. Increasing vapor pressure may be achieved by increasing the temperature or by increasing the enthalpy of vaporization, which requires a chemical reaction to convert the material into a more volatile material. For example, solid Si may have a vapor pressure <1E-6 Torr at 25° C., while the boiling point of SiF₄ may be −86° C. so the vapor pressure is greater than 760 Torr at 25° C. Some materials like indium, gallium and zinc react with halogen plasmas to form halides like InCl₃, InF₃, GaCl₃, GaF₃, ZnCl₂ and ZnF₂ that have higher vapor pressure than the parent elements, but too low for effective removal from semiconductor device structures at room temperature. Raising the temperature to increase the vapor pressure may not be an option due to device and integration limitations, so the apparatus and methods herein advantageously reduce the rate of condensed byproduct formation to below the rate of condensed byproduct sublimation.

For the purpose of this example, the element indium will be used, wherein indium reacts with a plasma species X to form a solid substance InX₃₍ₛ₎ where X may be an atom like F or Cl or a molecular radical or ligand like CF₃ and the parent element is not limited to indium but may include any other element like Ga, Zn, Mn, Fe, Pt, Cu, etc.

At equilibrium, the solid and gas phase concentrations of the substance do not change because the rates of sublimation and condensation are equal, as shown in the following:

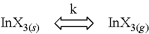

Here, K is the equilibrium constant which is equal to the concentration of the reaction products divided by the concentration or activity of the reactants. K is given by:

$$K = \frac{[ {InX}_{3 ( g )} ]}{[ {InX}_{3 ( s )} ]}$$

The concentration of the solid substance equals the concentration of the gas phase substance divided by the equilibrium constant, as shown below, thus removal of material from the gas phase causes the equilibrium to shift so more solid is converted to gas to replace material that has been removed.

$$[ {InX}_{3 ( s )} ] = \frac{[ {InX}_{3 ( g )} ]}{[ K ]}$$

The forward and backward reactions combine to form the equilibrium condition. Gas phase species are created by sublimation of the solid species with the rate constant k₁. For areas of the wafer surface outside of the impact area of the ion beam, solid substance is created by condensation of the gas phase substance with the rate constant k₋₁.

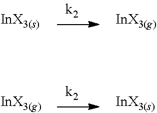

The rate constant k, as shown below, is a function of the frequency factor, A, and an exponential function of activation energy, E, and temperature, T.

k=Ae^{-E/RT}

The equilibrium constant K, as shown below, is equal to the quotient of the rate constant for sublimation, k₁, and the rate constant for condensation, k₋₁.

$$K = \frac{{k}_{1}}{{k}_{- 1}}$$

For a process chamber equipped with vacuum pumping, some gas phase substance is removed by transport through the vacuum pumps with the transport rate constant k₂.

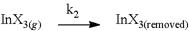

The rate of removal of the solid substance is equal to the sublimation rate constant, times the concentration of the solid substance, minus the condensation rate constant, and times the concentration of the gas phase substance. Reducing the gas phase concentration will reduce the rate of material condensation back on the semiconductor device structure. This is demonstrated by the following:

−d[InX₃₍ₛ₎]/dt=k₁[InX₃₍ₛ₎]−k₋₁[InX_{3(g)}]

The rate of formation of the gas phase substance is equal to the sublimation rate constant times the concentration of the solid substance minus the condensation rate constant times the concentration of the gas phase substance minus the transport rate constant times the concentration of the gas phase substance. As noted above, reducing the gas phase concentration will reduce the condensation rate. Additionally, increasing the transport rate constant, k₂, by increasing the conductance and/or the vacuum pumping speed, will also decrease the gas phase concentration resulting in less condensation of material back on the semiconductor device structure. This is demonstrated by the following:

d[InX_{3(g)}]/dt=k₁[InX₃₍ₛ₎]−k₋₁[InX_{3(g)}]−k₂[InX_{3(g)}]

Advantageously, as will be described in greater detail below, embodiments of the present disclosure increase conductance of gas phase material away from the device structure, increase surface temperature to increase vapor pressure and sublimation rate, and decrease gas phase pressure to decrease back scattering and condensation of material on the semiconductor device structure.

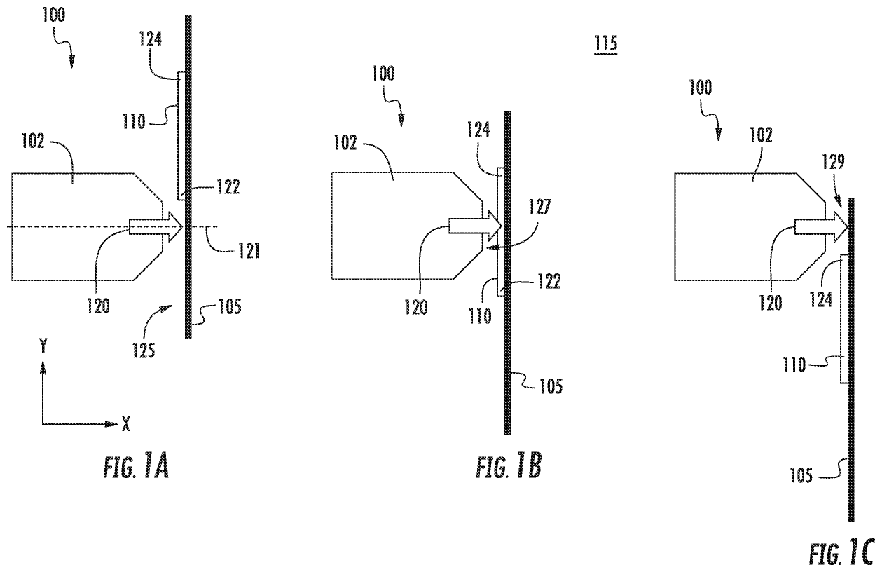

FIGS. 1A-1C demonstrate an approach for varying scan speed according to embodiments of the present disclosure. As shown, a system 100 may include an ion or plasma source 102, and a wafer assembly 103 within a process chamber 115. In some embodiments, the wafer assembly 103 includes a halo 105 connected with a substrate or wafer 110. The wafer 110 may include wafer perimeter defined by a bottom wafer edge 122 opposite a top wafer edge 124. The plasma source 102 may generate an ion beam 120 configured to impact the wafer 110 along an ion beam line 121. In this embodiment, the halo 105 and the wafer 110 may move relative to the plasma source 102, e.g., along the y-direction. However, in other embodiments, the plasma source 102 may move relative to the wafer 110, which is stationary. Although not shown, it will be appreciated that numerous (e.g., thousands) 3-D semiconductor devices may be present on the wafer 110.

As shown in FIG. 1A, reduction of scan speed in a first (e.g., high conductance) area 125, at a top of a scan stroke, after a bottom wafer edge 122 of the wafer 110 has passed above the ion beam 120, will position the wafer in a very low pressure ([InX3(g)]≤2E-5 Torr) region where the condensation rate [k₋₁[InX3(g)] is lower than the sublimation rate and net solid removal occurs. As shown, the first area 125 may generally correspond to a portion of the halo 105 located below (along the y-direction) the wafer 110. Selection of the reduced scan speed may be selected to allow sufficient time for complete removal of solid reaction byproducts. Although non-limiting, this stroke distance may be 75 mm in the current configuration and reduction of the scan speed to zero, if necessary, to allow more time for net solid byproduct removal.

As shown in FIG. 1B, the scan speed can be increased on the down stroke so that the wafer 110 is at a desired scan speed when the ion source 102 is across from or aligned with the wafer 110 in a second (e.g., low conductance) area 127. When the ion source 102 is aligned with the wafer 110, ions and radicals from the ion beam 120 may remove specific material and create low volatility reaction byproducts.

As shown in FIG. 1C, reduction of scan speed, at a bottom of the scan stroke, e.g., after a top wafer edge 124 of the wafer 110 has passed below the ion beam 120, will allow sublimation of reaction byproducts in a third (e.g., high conductance) area 129 of the process chamber 115. As shown, the third area 129 may generally correspond to a portion of the halo 105 located above (along the y-direction) the wafer 110. Although non-limiting, the scan stroke distance may be approximately 75 mm in the current configuration.

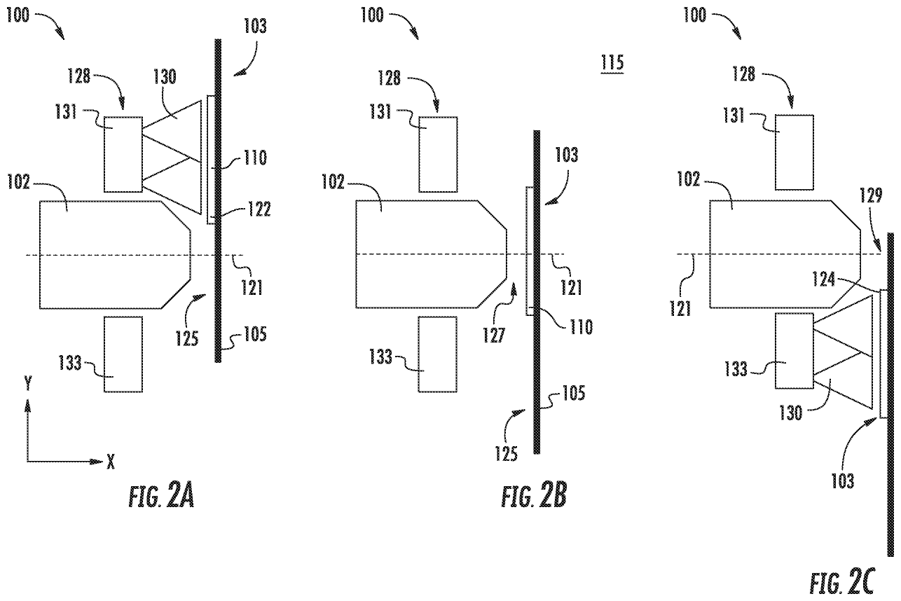

FIGS. 2A-2C demonstrate varying a temperature of the wafer assembly 103 according to embodiments of the present disclosure. As shown, an illumination source (e.g., an LED heat lamp) or other radiation source may be used to increase a surface temperature of the wafer 110 (and semiconductor devices formed thereon) as well as the low volatility reaction byproducts. As a result, vapor pressure will be increased through Pᵥ=ΔH_{vap,m}/RT and the sublimation rate constant through: k=Ae−E/RT. Although non-limiting, the illumination source 128 may generally be offset (e.g., above and below in the y-direction) from the ion beam line 121. As shown, the illumination source 128 may include one or more illumination components 131, 133 for delivering illumination beams 130 to the wafer assembly 103. In some embodiments, the illumination source 128 may continuously provide the illumination beams 130 to the wafer 110 regardless of the relative position between the ion source 102 and the wafer assembly 103, and then shuttered/unshuttered as desired. In other embodiments, the illumination beams 130 may be switched on/off as the ion source 102 and the wafer assembly 103 move relative to one another.

In some embodiments, as shown in FIG. 2A, the illumination beams 130 may impact the wafer 110 when the ion source 102 and the ion beam line 121 are across from, and generally aligned with, the first area 125, which is below the bottom wafer edge 122. As shown, illumination component 131 may deliver the illumination beams 130. As the wafer assembly 103 moves relative to the ion source 102 and the illumination source 128, as shown in FIG. 2B, the ion source 102 and ion beam line 121 are across from, and generally aligned with, the wafer 110, which correlates with the second area 127. The illumination source 128 may cease providing the illumination beams 130 to the wafer assembly 103 when the ion source 102 is proximate the wafer 110.

In FIG. 2C, the illumination beams 130 may impact the wafer 110 when the ion source 102 and the ion beam line 121 are across from, and generally aligned with, the third area 129, which is above the top wafer edge 124. As shown, illumination component 133 may deliver the illumination beams 130.

It will be appreciated that the illumination source 128 may not be limited to LEDs, and that other sources of radiation and heat may be used. Furthermore, the illumination beam 130 may be continuous or pulsed in various embodiments. It will be appreciated that the illumination source 128 and the illumination beams 130 may be combined with a variable scan speed, such as the variable scan speed shown in FIGS. 1A-1C and described above.

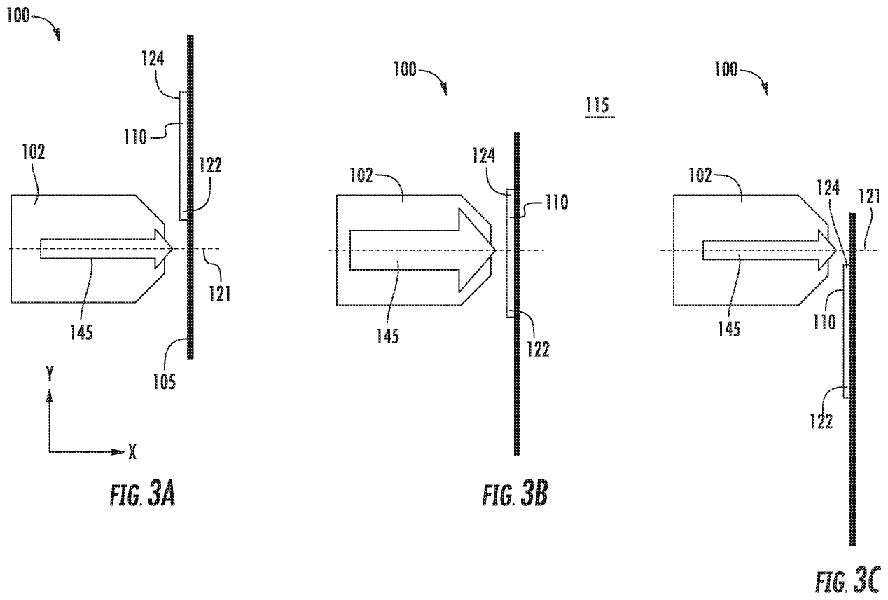

FIGS. 3A-3C demonstrate varying a gas flow rate at the wafer assembly 103 according to embodiments of the present disclosure. As demonstrated in FIG. 3A, a gas flow 145 may be delivered towards the wafer assembly 103 at a first gas flow rate when the ion source 102 is positioned below the wafer 110. As demonstrated, the ion source 102 and ion beam line 121 are across from, and generally aligned with, the first area 125 of the wafer assembly 103. Said another way, a reduction of process gas flow 145 may occur when the wafer 110 is in a high conductance region, at a top of the scan stroke, e.g., after the bottom wafer edge 122 of the wafer 110 has passed above the ion beam line 121. This may cause the wafer 110 to experience very low pressure ([InX_{3(g)}]≤1E-5 Torr), where the condensation rate [k₋₁[InX_{3(g)}] is lower than the sublimation rate and net solid removal occurs.

Process gas flow 145 can be increased on the down stroke so that the ion source 102 is at a desired gas flow and pressure when the wafer 110 is in front of the source 102. For example, as shown in FIG. 3B, the gas flow 145 may be delivered towards the wafer assembly 103 at a second gas flow rate when the ion source 102 is positioned across from the wafer 110. The ion source 102 and ion beam line 121 are generally aligned with the second area 127 of the wafer assembly 103. As a result, the ions and radicals of the ion beam may remove specific material and create low volatility reaction byproducts.

As shown in FIG. 3C, the gas flow 145 may be delivered towards the wafer assembly at a third gas flow rate when the ion source 102 is positioned above the wafer 110. The ion source 102 and ion beam line 121 are generally aligned with the third area 129 of the wafer assembly 103. Reduction of process gas flow 145, at the bottom of the stroke, after the top wafer edge 124 of the wafer 110 has passed below the ion beam line 121, will allow sublimation of reaction byproducts in the low-pressure conditions that result from the reduction in gas flow. This distance may be 75 mm in one non-limiting configuration. In some embodiments, the second gas flow rate is greater than the first gas flow rate and the third gas flow rate. It will be appreciated that variable process gas flow 145 may be combined with heating from the illumination source 128 and/or the variable scan speed, as described above.

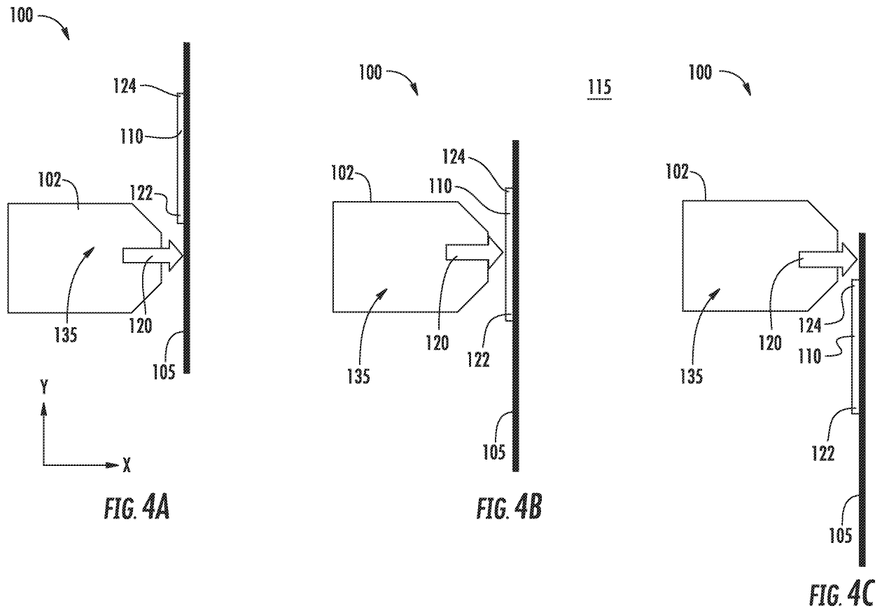

FIGS. 4A-4C show the relative positions of the plasma source 102, the halo 105, and the wafer 110 in high and low conductance regions and high and low plasma source power level settings of the process chamber 115. As shown in FIG. 4A, reduction of plasma source power level 135 may be provided when the wafer 110 is in the high conductance region, at top of the stroke, after the bottom wafer edge 122 of the wafer 110 has passed above the ion beam line 121. As a result, a reduced molecular dissociation within the source 102, and hence reduced pressure at the wafer surface ([InX_{3(g)}]≤1E-5 Torr) where the condensation rate [k₋₁[InX_{3(g)}] is lower than the sublimation rate and net solid removal occurs.

As shown in FIG. 4B, plasma source power level 135 can be increased on the down stroke so that the plasma source is at BKM power when the wafer 110 is in front of the source 102 where the ions and radicals remove specific material and create low volatility reaction byproducts. As shown in FIG. 4C, reduction of plasma source power level 135, at bottom of the stroke, after the top wafer edge 124 of the wafer 110 has passed below the ion beam 120 will allow sublimation of reaction byproducts in the low-pressure conditions that result from the reduction in plasma source power. This distance may be 75 mm in the current configuration. It will be appreciated that variable source power may be used in conjunction with any of the other embodiments described herein, including variable scan speed, LED heating, and variable gas flow.

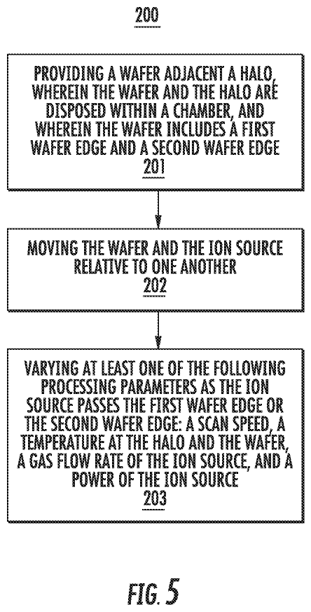

FIG. 5 is a flowchart depicting a method 200 according to embodiments of the present disclosure. At block 201, the method 200 may include providing a wafer adjacent a halo, wherein the wafer and the halo are disposed within a chamber, and wherein the wafer includes a first wafer edge and a second wafer edge. In some embodiments, the wafer is directly coupled to the halo.

At block 202, the method 200 may include moving the wafer and the ion source relative to one another. In some embodiments, the halo and the wafer may move relative to the plasma source. However, in other embodiments, the plasma source may move relative to the wafer, which is stationary.

At block 203, the method 200 may include varying at least one of the following processing parameters as the ion source passes the first wafer edge or the second wafer edge: a scan speed, a temperature at the halo and the wafer, a gas flow rate of the ion source, and a power of the ion source.

In some embodiments, varying the scan speed includes moving the halo and the wafer relative to the ion source at a first speed as an ion beam impacts the halo in an area above the first wafer edge, and moving the halo and the wafer relative to the ion source at a second speed as the ion beam impacts the wafer. Varying the scan speed may further include moving the halo and the wafer relative to the ion source at a third speed as the ion beam impacts the halo in a second area, below the second wafer edge, wherein the second speed is greater than the first speed and the third speed.

In some embodiments, varying the temperature may include providing a heating source, delivering heat from the heating source to the wafer, wherein the heat is delivered to the wafer when the ion source is positioned above or below the wafer, and wherein the heat is not delivered to the wafer when the ion source is positioned across from the wafer.

In some embodiments, varying the gas flow rate of the ion source may include delivering a gas towards the halo and the wafer at a first gas flow rate when the ion source is positioned below the wafer, and delivering the gas towards the halo and the wafer at a second gas flow rate when the ion source is positioned across from the wafer. The method may further include delivering the gas towards the halo and the wafer at a third gas flow rate when the ion source is positioned above the wafer, wherein the second gas flow rate is greater than the first gas flow rate and the third gas flow rate.

In various embodiments, design tools can be provided and configured to create the datasets used to pattern the semiconductor layers as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

For the sake of convenience and clarity, terms such as “top,” “bottom,” “upper,” “lower,” “vertical,” “horizontal,” “lateral,” and “longitudinal” are used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
providing a wafer adjacent a halo, wherein the wafer and the halo are disposed within a chamber, and wherein the wafer includes a first wafer edge and a second wafer edge;
moving the wafer and an ion source relative to one another; and
varying at least one of the following processing parameters as the ion source passes the first wafer edge or the second wafer edge: a scan speed, a temperature at the halo and the wafer, a gas flow rate of the ion source, and a power of the ion source.

2. The method of claim 1, wherein varying the scan speed comprises:
moving the halo and the wafer relative to the ion source at a first speed as an ion beam impacts the halo in an area above the first wafer edge;
moving the halo and the wafer relative to the ion source at a second speed as the ion beam impacts the wafer; and
moving the halo and the wafer relative to the ion source at a third speed as the ion beam impacts the halo in a second area, below the second wafer edge, and wherein the second speed is greater than the first speed and the third speed.

3. The method of claim 2, wherein the first speed is approximately equal to the third speed.

4. The method of claim 1, wherein varying the temperature comprises:
providing a heating source; and
delivering heat from the heating source to the wafer, wherein the heat is delivered to the wafer when the ion source is positioned above or below the wafer, and wherein the heat is not delivered to the wafer when the ion source is positioned across from the wafer.

5. The method of claim 4, wherein delivering the heat comprises delivering an illumination beam to the wafer.

6. The method of claim 1, wherein varying the gas flow rate of the ion source comprises:
delivering a gas towards the halo and the wafer at a first gas flow rate when the ion source is positioned below the wafer;
delivering the gas towards the halo and the wafer at a second gas flow rate when the ion source is positioned across from the wafer; and
delivering the gas towards the halo and the wafer at a third gas flow rate when the ion source is positioned above the wafer, wherein the second gas flow rate is greater than the first gas flow rate and the third gas flow rate.

7. The method of claim 6, wherein the first gas flow rate is approximately equal to the third gas flow rate.

8. The method of claim 1, wherein varying the power of the ion source comprises:
operating the ion source at a first power level when the ion source is positioned below the wafer;
operating the ion source at a second power level when the ion source is positioned across from the wafer; and
operating the ion source at a third power level when the ion source is positioned above the wafer, wherein the second power level is greater than the first power level and the third power level.

9. The method of claim 8, wherein the third power level is approximately equal to the first power level.

10. A method of removing material and byproducts from a semiconductor device, the method comprising:
providing a wafer connected to a halo, wherein the wafer and the halo are disposed within a chamber, and wherein the wafer includes a first wafer edge and a second wafer edge;
scanning the wafer with an ion source; and
varying at least one of the following processing parameters as the ion source scans over the first wafer edge or the second wafer edge: a scan speed, a temperature at the halo and the wafer, a gas flow rate of the ion source, and a power of the ion source.

11. The method of claim 10, wherein varying the scan speed comprises:
moving the halo and the wafer relative to the ion source at a first speed when an ion beam impacts the halo in a first area above the first wafer edge;
moving the halo and the wafer relative to the ion source at a second speed when the ion beam impacts the wafer; and
moving the halo and the wafer relative to the ion source at a third speed when the ion beam impacts the halo in a second area, below the second wafer edge, and wherein the second speed is greater than the first speed and the third speed.

12. The method of claim 10, wherein varying the temperature comprises delivering an illumination beam from a heating source to the wafer, wherein the illumination beam is delivered to the wafer when the ion source is positioned above or below the wafer, and wherein the illumination beam is not delivered to the wafer when the ion source is positioned across from the wafer.

13. The method of claim 10, wherein varying the gas flow rate of the ion source comprises:
delivering a gas towards the halo and the wafer at a first gas flow rate when the ion source is positioned below the wafer;
delivering the gas towards the halo and the wafer at a second gas flow rate when the ion source is positioned across from the wafer; and
delivering the gas towards the halo and the wafer at a third gas flow rate when the ion source is positioned above the wafer, wherein the second gas flow rate is greater than the first gas flow rate and the third gas flow rate.

14. The method of claim 10, wherein varying the power of the ion source comprises:
operating the ion source at a first power level when the ion source is positioned below the wafer;
operating the ion source at a second power level when the ion source is positioned across from the wafer; and
operating the ion source at a third power level when the ion source is positioned below the wafer, wherein the second power level is greater than the first power level and the third power level.

15. A method of removing material and byproducts from a semiconductor device, the method comprising:
providing a wafer assembly within a chamber, wherein the wafer assembly includes a wafer coupled to a halo, and wherein the wafer is defined by a wafer perimeter;
scanning the wafer and the halo with an ion source; and
processing the wafer according to a first set of processing parameters when the ion source is aligned with a first area of the halo located outside the wafer perimeter or a second area of the halo located outside the wafer perimeter; and
processing the wafer according to a second set of processing parameters when the ion source is aligned with the wafer, wherein the first and second sets of processing parameters include: a scan speed, a temperature at the halo and the wafer, a gas flow rate of the ion source, or a power of the ion source.

16. The method of claim 15, further comprising changing between the first set of processing parameters and the second set of processing parameters by varying the scan speed, wherein varying the scan speed, comprises:
moving the halo and the wafer relative to the ion source at a first speed when an ion beam impacts the halo in the first area of the wafer outside the wafer perimeter;
moving the halo and the wafer relative to the ion source at a second speed when the ion beam impacts the wafer; and
moving the halo and the wafer relative to the ion source at a third speed when the ion beam impacts the halo in the second area of the halo outside the wafer perimeter, wherein the second speed is greater than the first speed and the third speed.

17. The method of claim 15, further comprising changing between the first set of processing parameters and the second set of processing parameters by varying the temperature, wherein varying the temperature comprises delivering an illumination beam from a heating source to the wafer, wherein the illumination beam is delivered to the wafer when the ion source is aligned with the first or second areas of the halo outside the wafer perimeter, and wherein the illumination beam is not delivered to the wafer when the ion source is aligned with the wafer.

18. The method of claim 15, further comprising changing between the first set of processing parameters and the second set of processing parameters by varying the gas flow rate of the ion source, wherein varying the gas flow rate, comprises:
delivering a gas towards the halo and the wafer at a first gas flow rate when the ion source is aligned with the first or second areas of the halo outside the wafer perimeter; and
delivering the gas towards the halo and the wafer at a second gas flow rate when the ion source is positioned across from the wafer.

19. The method of claim 15, further comprising changing between the first set of processing parameters and the second set of processing parameters by varying the power of the ion source, wherein varying the power comprises:
operating the ion source at a first power level when the ion source is aligned with the first or second areas of the halo outside the wafer perimeter; and
operating the ion source at a second power level when the ion source is positioned across from the wafer.
